(19) United States
(12) Patent Application Publication
(10) Pub. No.: US 2007/0238319 A1
(43) Pub. Date: Oct. 11, 2007

(54) Mechanically actuated nanotube switches

(76) Inventors: Nels E. Jewell-Larsen, Seattle, WA (US); Stephen W. Montgomery, Seattle, WA (US); Joseph T. Dibene, Olympia, WA (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/217,731

(22) Filed: Aug. 31, 2005

(51) Int. Cl. H01L 21/31

(52) U.S. Cl. 438/785

(57) ABSTRACT

Some embodiments of the present invention include apparatuses and methods relating to nanotube switches that are mechanically actuated.

### TECHNICAL FIELD

Embodiments of the invention relate to microelectronics technology. In particular, embodiments of the invention relate to mechanically actuated nanotube switches.

### BACKGROUND

In microelectronic components, such as microprocessors, switches are used in integrated circuit (IC) designs for a variety of purposes, such as to create logic devices. Typically, transistors implemented in a semiconductor material, such as Silicon, provide switching for ICs. In order to increase the performance of ICs, Silicon based transistors have been made smaller and more advanced. Silicon based transistors may fail to meet continued demands of IC performance, however, because of limits in how small they can be made and fundamental limits in the Silicon material.

### BRIEF DESCRIPTION OF THE DRAWINGS

The invention is illustrated by way of example and not by way of limitation in the figures of the accompanying drawings, in which the like references indicate similar elements and in which:

FIGS. 1A-1B illustrate an apparatus in accordance with an embodiment of the present invention.

FIG. 2 illustrates an apparatus in accordance with an embodiment of the present invention.

FIG. 3 illustrates an apparatus in accordance with an embodiment of the present invention.

FIG. 4 illustrates a schematic of a system in accordance with an embodiment of the present invention.

### DETAILED DESCRIPTION

In various embodiments, apparatuses and methods relating to nanotube switches are described. However, various embodiments may be practiced without one or more of the specific details, or with other methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

To meet continued integrated circuit (IC) performance requirements a new switch technology may be needed. In particular, a nanoscale switch including a nanotube connected between two electrodes and actuated by an axial strain may be implemented in an IC to provide enhanced performance over existing technologies. The nanotube switch may provide enhancements such as negligible electromigration, extremely small feature sizes, the characteristic of sustaining high current densities at high temperatures, excellent thermal conductivity, and others.

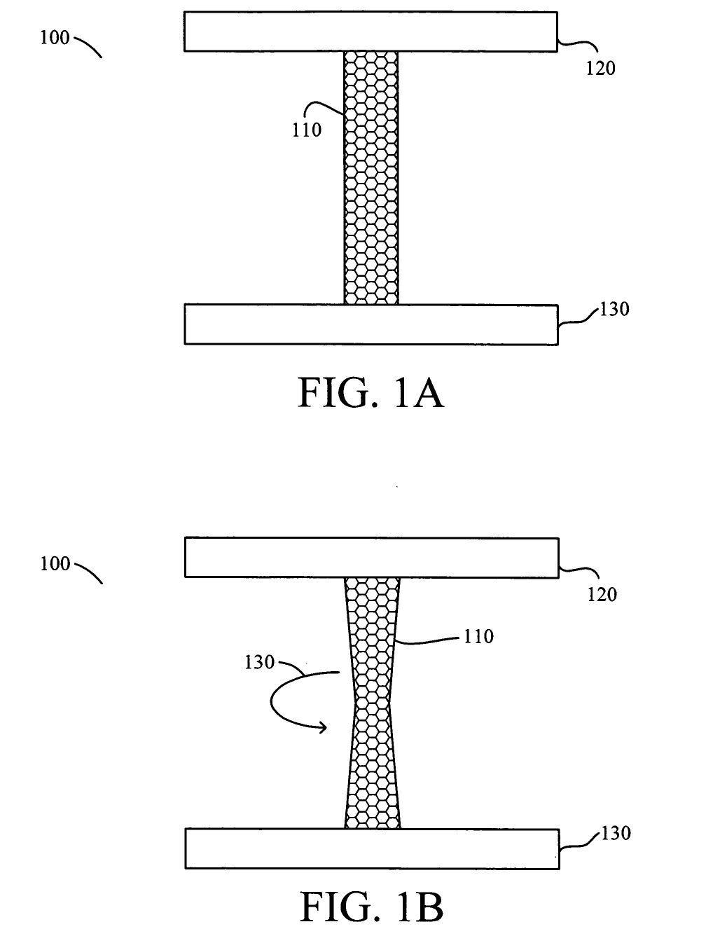

FIG. 1A illustrates a node 100 including a nanotube 110, an electrode 120, and an electrode 130. FIG. 1B illustrates an axial strain 130 and nanotube 110 twisted under axial strain 130. By inducing axial strain 130 on nanotube 110 the electrical resistance of nanotube 110 may increase exponentially. The increase in electrical resistance may be due to deformation of the walls of nanotube 110 which causes the mean free path of ballistic electron transport in the nanotube to decrease. The mean free path may be the theoretical length an electron travels before it encounters an obstruction. In general, a shorter mean free path will cause greater resistance.

By inducing axial strain 130, node 100 may act as a switch. In an embodiment, under no (or little) axial strain (FIG. 1A), the resistance may be relatively low and node 100 may be closed, and under axial strain 130 (FIG. 1B), the resistance may be high and node 100 may be open. In such embodiments, node 100 may be a binary switch that allows current flow in the closed state and allows no (or little) current flow in the open state.

In other embodiments, node 100 may be a switch that has more than two states. By introducing various levels of axial strains, node 100 may provide corresponding levels of current flow. Providing a switch with more than two states may provide greater flexibility in designing and implementing ICs. As is further discussed below, under variable axial strains, node 100 may also act as a variable transistor.

Nanotube 110 may include any material and may be any type of nanotube or wire. In an embodiment, nanotube 110 may be a carbon nanotube. Any number of nanotubes may be connected between electrodes 120, 130 in node 100. In an embodiment, one nanotube may be connected between electrodes 120, 130. In another embodiment, several nanotubes may be connected between electrodes 120, 130. In other embodiments, thousands, millions, or billions of nanotubes may be connected between electrodes 120, 130. In an embodiment, the number of nanotubes connected between electrodes 120, 130 may be chosen based on a desired closed circuit resistance.

Nanotube 110 may be twisted to any angle to cause a switch in node 100. In an embodiment, nanotube 110 may be twisted to an angle of about 90 degrees. In another embodiment nanotube 110 may be twisted to an angle in the range of 45 to 135 degrees. In an embodiment, nanotube 110 may be twisted to an angle in the range of about 30 to 90 degrees. In an embodiment, switching node 100 may cause no (or little) fatigue in nanotube 110 due to the high intermolecular bond strength and nearly perfect lattice structure of nanotube 110.

By inducing axial strain 130, node 100 may act as a variable resistor. In an embodiment, a variable axial strain may be applied to vary the electrical resistance of node 100. In an embodiment, a greater axial strain will cause greater electrical resistance in node 100.

Electrodes 120, 130 may be any suitable conductive material. In an embodiment, electrodes 120, 130 may include copper.

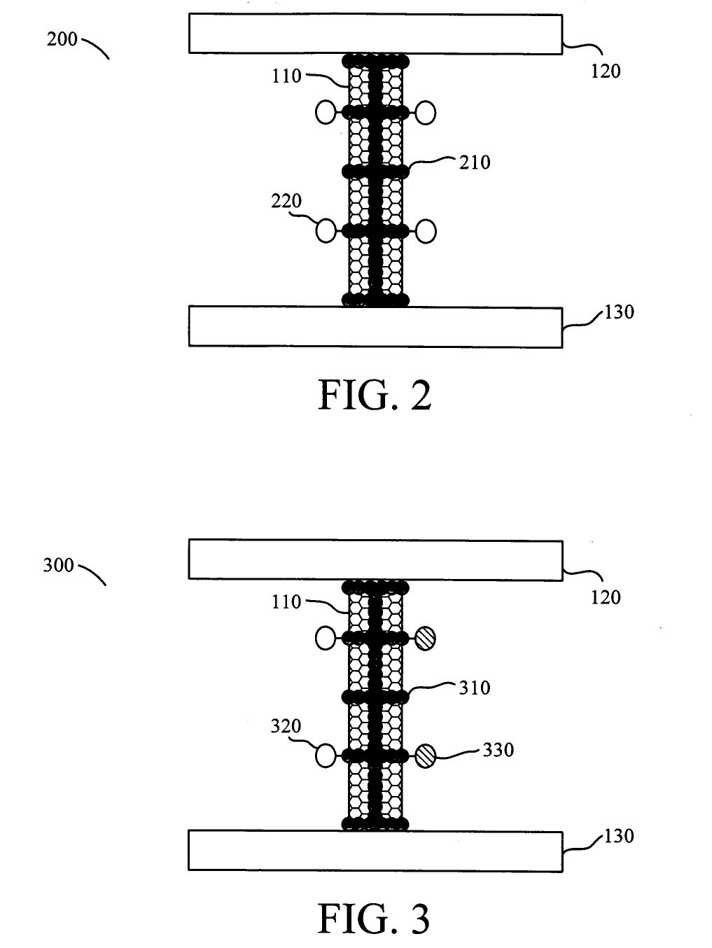

FIG. 2 illustrates node 200 including nanotube 110, electrodes 120, 130, attachment molecule 210, and magnetic particles 220.

An axial strain (as illustrated in FIG. 1B) may be induced on nanotube 110 by a magnetic field (not shown) acting on magnetic particles 220 which may in turn induce a force on nanotube 110. The magnetic field may cause force on magnetic particles 220 that in turn twists nanotube 110. In such a manner, node 200 may be a switch or variable transistor as discussed above.

Attachment molecule 210 may be any suitable material and may be applied to nanotube 110 in any suitable arrangement. In an embodiment, attachment molecule 210 may include a polymer. In an embodiment, attachment molecule 210 may include polyphenylene ether (PPE). In an embodiment, attachment molecule 210 may be applied along the length of nanotube 110. In another embodiment, attachment molecule 210 may be applied to a portion of nanotube 110. In an embodiment, attachment molecule 210 may be applied to a central portion of nanotube 110. In an embodiment, attachment molecule 210 may be attached to nanotube 110 by non-covalent bonding, such as by van der Waals forces. In an embodiment, attachment molecule 210 may not be required and magnetic particles 220 may be directly connected to nanotube 110.

Magnetic particles 220 may be any suitable material that interacts with the magnetic field. In various embodiments, magnetic particles 220 may include a ferromagnetic material, a ferrimagnetic material, a paramagnetic material, or combinations thereof. In an embodiment, magnetic particles 220 may include iron. Any number of magnetic particles 220 may be used and they may be situated in any suitable manner. In an embodiment, 4 to 12 magnetic particles 220 may be used. In another embodiment, 4 to 8 magnetic particles 220 may be used. In an embodiment, 6 to 12 magnetic particles 220 may be used. In an embodiment, magnetic particles 220 may be aligned along edges of nanotube 110. In an embodiment, magnetic particles 220 may be aligned along 2 edges of nanotube 110. In another embodiment, magnetic particles 220 may be aligned along 4 edges of nanotube 110.

FIG. 3 illustrates node 300 including nanotube 110, electrodes 120, 130, attachment molecule 310, polar particles 320, and polar particles 330.

An axial strain (as illustrated in FIG. 1B) may be induced on nanotube 110 by an electric field (not shown) acting on polar particles 320, 330 which may in turn induce a force on nanotube 110. In such a manner, node 300 may be a switch or variable transistor as discussed above.

Attachment molecule 310 may be any suitable material and may be applied to nanotube 110 in any suitable arrangement. In an embodiment, attachment molecule 310 may include a polymer. In an embodiment, attachment molecule 310 may include polyphenylene ether (PPE). In an embodiment, attachment molecule 310 may be applied along the length of nanotube 110. In another embodiment, attachment molecule 310 may be applied to a portion of nanotube 110. In an embodiment, attachment molecule 310 may be applied to a central portion of nanotube 110. In an embodiment, attachment molecule 310 may be attached to nanotube 110 by non-covalent bonding, such as by van der Waals forces. In an embodiment, attachment molecule 310 may not be required and magnetic particles 220 may be directly connected to nanotube 110.

Polar particles 320, 330 may be any suitable material that interacts with the electric field. In various embodiments, polar particles 320, 330 may include electronegative materials or electropositive materials. In an embodiment, polar particles 320, 330 may include oxygen or fluorine. In an embodiment, polar particles 320, 330 may be of opposite polarity. In another embodiment, polar particles of only one polarity (positive or negative) may be used.

Any number of polar particles 320, 330 may be used and they may be situated in any suitable manner. In an embodiment, 4 to 12 polar particles 320, 330 of one polarity may be used. In an embodiment, 4 to 24 polar particles of opposite polarity may be used. In an embodiment, magnetic particles 220 may be aligned along edges of nanotube 110. In an embodiment, polar particles 320, 330 may be aligned along 2 edges of nanotube 110. In another embodiment, polar particles 320, 330 of opposite polarity may be aligned along two opposing edges of nanotube 110. In another embodiment, polar particles 320, 330 may be aligned along 4 edges of nanotube 110. In an embodiment, polar particles 320, 330 of opposite polarity may be alternated around 4 edges of nanotube 110.

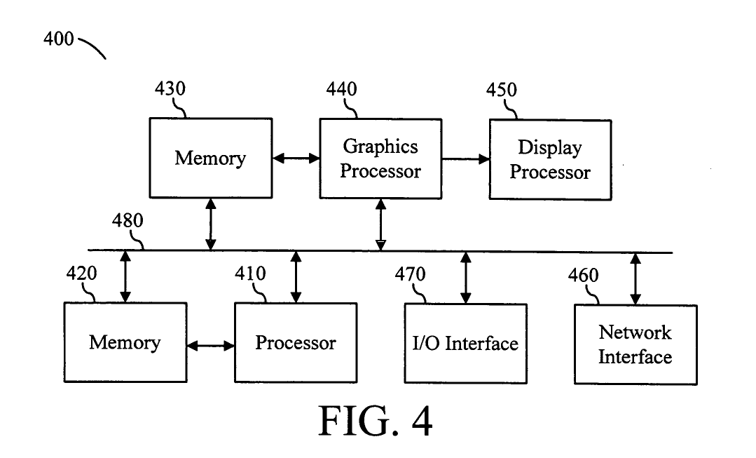

As illustrated in FIG. 4, the switches or variable resistors discussed above may be incorporated into a system 400. System 400 may include a processor 410, a memory 420, a memory 440, a graphics processor 440, a display processor 450, a network interface 460, an I/O interface 470, and a communication bus 480. In an embodiment, memory 420 may include a volatile memory component. Any of the components in system 400 may include the switches or variable resistors. In an embodiment, processor 410 may include the switches or variable resistors. In another embodiment, graphics processor 440 may include the switches or variable resistors. A large number of combinations of components including the switches or variable resistors may be available.

Reference throughout this specification to “one embodiment” or “an embodiment” means that a particular feature, structure, material, or characteristic described in connection with the embodiment is included in at least one embodiment of the invention. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. An apparatus comprising:
a nanotube connected to a first electrode and a second electrode; and
a particle attached to the nanotube to apply an axial force on the nanotube in response to an energy field.

2. The apparatus of claim 1, wherein the nanotube comprises a carbon nanotube.

3. The apparatus of claim 1, wherein the particle is attached to the nanotube by an attachment molecule.

4. The apparatus of claim 3, wherein the attachment molecule comprises a polymer.

5. The apparatus of claim 4, wherein the polymer extends along the nanotube.

6. The apparatus of claim 4, wherein the polymer is non-covalently bonded to the nanotube.

7. The apparatus of claim 1, wherein the particle is a magnetic particle and the energy field is a magnetic field.

8. The apparatus of claim 7, wherein the magnetic particle comprises at least one of a ferromagnetic material, a ferrimagnetic material, or a paramagnetic material.

9. The apparatus of claim 7, wherein the magnetic particle comprises iron.

10. The apparatus of claim 1, wherein the particle is a polar particle and the energy field is an electric field.

11. The apparatus of claim 10, wherein the polar particle comprises at least one of oxygen or fluorine.

12. The apparatus of claim 10, further comprising:
a second polar particle attached to the nanotube, wherein the first polar particle and the second polar particle have opposite polarities.

13. The apparatus of claim 1, further comprising:
a plurality of particles attached to the nanotube to apply an axial force on the nanotube in response to the energy field, wherein the particles are aligned along two edges of the nanotube.

14. The apparatus of claim 1, further comprising:
a plurality of nanotubes connected to the first electrode and the second electrode; and
a plurality of particles attached to the nanotubes to apply an axial force on the nanotubes.

15. The apparatus of claim 1, further comprising:
a switch including the first electrode, the second electrode, and the nanotube, wherein the switch is controlled by the energy field.

16. The apparatus of claim 1, further comprising:
a variable resistor including the first electrode, the second electrode, and the nanotube, wherein the variable resistor is controlled by the energy field.

17. A method comprising:
inducing a strain around the axis of a nanotube connected to a first and second electrode by applying an energy field to affect a particle attached to the nanotube.

18. The method of claim 17, wherein the nanotube comprises a carbon nanotube.

19. The method of claim 17, wherein the particle is a magnetic particle and the energy field is a magnetic field.

20. The method of claim 17, wherein the particle is a polar particle and the energy field is an electric field.

21. The method of claim 17, wherein the particle is attached to the nanotube by a polymer that extends along the nanotube.

22. The method of claim 17, further comprising:
controlling a switch by applying the energy field.

23. The method of claim 22, wherein the switch is part of an integrated circuit.

24. The method of claim 17, further comprising:
controlling a variable resistor by applying the energy field.

25. The method of claim 17, further comprising:
opening an electrical node by applying the energy field.

26. A system comprising:
a microprocessor having a switch including a nanotube connected to a first electrode and a second electrode and a particle attached to the nanotube to apply an axial force on the nanotube in response to an energy field; and
a display processor.

27. The system of claim 26, further comprising:
a volatile memory component.
